(19) United States
(12) Patent Application Publication
(10) Pub. No.: US 2021/0305324 A1
(43) Pub. Date: Sep. 30, 2021

(54) COLOR FILTER ARRAY, ELECTRONIC DEVICE, AND METHOD OF MANUFACTURING COLOR FILTER ARRAY

(71) Applicant: CANON KABUSHIKI KAISHA, Tokyo (JP)

(72) Inventors: Yoshihisa Kawamura, Kanagawa (JP); Hideki Ina, Tokyo (JP); Yuto Nozaki, Kanagawa (JP); Yusuke Todo, Kanagawa (JP); Atsushi Kanome, Kanagawa (JP); Norihiko Nakata, Kanagawa (JP); Toru Eto, Kanagawa (JP)

(21) Appl. No.: 17/205,170

(22) Filed: Mar. 18, 2021

(30) Foreign Application Priority Data
Mar. 30, 2020 (JP) 2020-061116
Dec. 18, 2020 (JP) 2020-210593

(51) Int. Cl. H01L 27/32; H01L 51/56; H01L 51/52

(52) U.S. Cl. CPC H01L 27/322; H01L 51/5284; H01L 51/56

(57) ABSTRACT

A color filter array is provided. The array comprises a first color filter, a second color filter, and a third color filter that are arranged on a base member and respectively have different colors. The first color filter and the third color filter are arranged adjacent to each other, the second color filter includes a portion placed between an end portion of the third color filter and the base member, and the end portion of the third color filter and the portion of the second color filter are in contact with the first color filter.

### BACKGROUND OF THE INVENTION

### Field of the Invention

The present invention relates to a color filter array, an electronic device, and a method of manufacturing the color filter array.

### Description of the Related Art

Display images and captured images are colored by using color filters for light-emitting elements and light-receiving elements. Japanese Patent Laid-Open No. 2019-185888 discloses a technique of suppressing a deterioration in color purity caused by stray light exiting from color filters having high relative luminosity by overlapping end portions of color filters having low relative luminosity on end portions of the color filters having high relative luminosity between adjacent pixels.

Display images and captured images require high color reproducibility.

Some embodiments of the present invention provide a technique advantageous in improving color reproducibility in a color filter array.

### SUMMARY OF THE INVENTION

According to some embodiments, a color filter array comprising a first color filter, a second color filter, and a third color filter that are arranged on a base member and respectively have different colors, wherein the first color filter and the third color filter are arranged adjacent to each other, the second color filter includes a portion placed between an end portion of the third color filter and the base member, and the end portion of the third color filter and the portion of the second color filter are in contact with the first color filter, is provided.

According to some other embodiments, a color filter array comprising a first color filter, a second color filter, and a third color filter that are arranged on a base member and respectively transmit light in a blue band, light in a green band, and a light in a red band, wherein the color filter array comprises: a first boundary region where the first color filter is adjacent to the third color filter; a second boundary region where the first color filter is adjacent to the second color filter; and a third boundary region where the second color filter is adjacent to the third color filter, wherein a light-shielding effect of the second boundary region and a light-shielding effect of the third boundary region are higher than a light-shielding effect of the first boundary region, is provided.

According to still other embodiments, a method of manufacturing a color filter array comprising a first color filter, a second color filter, and a third color filter that are arranged on a base member and respectively have different colors, the method comprising: forming the first color filter; forming the second color filter after the forming the first color filter; and forming the third color filter before the forming the first color filter or between the forming the first color filter and the forming the second color filter, wherein after the forming the first color filter and the forming the third color filter and before the forming the second color filter, the first color filter has an upper portion in contact with the third color filter and a lower portion that is arranged below the upper portion in a direction perpendicular to a surface of the base member, and is not in contact with the third color filter, and in the forming the second color filter, a concave portion formed between the lower portion and the third color filter is filled with part of the second color filter, is provided.

Further features of the present invention will become apparent from the following description of exemplary embodiments (with reference to the attached drawings).

### BRIEF DESCRIPTION OF THE DRAWINGS

FIGS. 1A to 1D are sectional views showing an example of the configuration of a color filter array according to an embodiment;

FIGS. 2A to 2C are plan views showing a method of manufacturing the color filter array in FIGS. 1A to 1D;

FIGS. 3A to 3C are views showing reticles when the color filter array in FIGS. 1A to 1D is manufactured;

FIGS. 4A and 4B are views for explaining the effects of the color filter array in FIGS. 1A to 1D;

FIGS. 5A and 5B are views showing a modification of the color filter array in FIGS. 1A to 1D;

FIGS. 6A and 6B are views showing a modification of the color filter array in FIGS. 1A to 1D;

FIG. 7 is a view showing a modification of the color filter array in FIGS. 1A to 1D;

FIGS. 8A and 8B are views showing a modification of the color filter array in FIGS. 1 to 1D;

FIGS. 9A to 9C are plan views showing a method of manufacturing the color filter array in FIGS. 8A and 8B;

FIGS. 10A and 10B are plan views showing a method of manufacturing the color filter array in FIGS. 8A and 8B;

FIGS. 11A to 11C are plan views showing a method of manufacturing the color filter array in FIGS. 8A and 8B; and

FIG. 12 is a view showing the spectral transmittance of the color filter array in FIGS. 1A to 1D.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

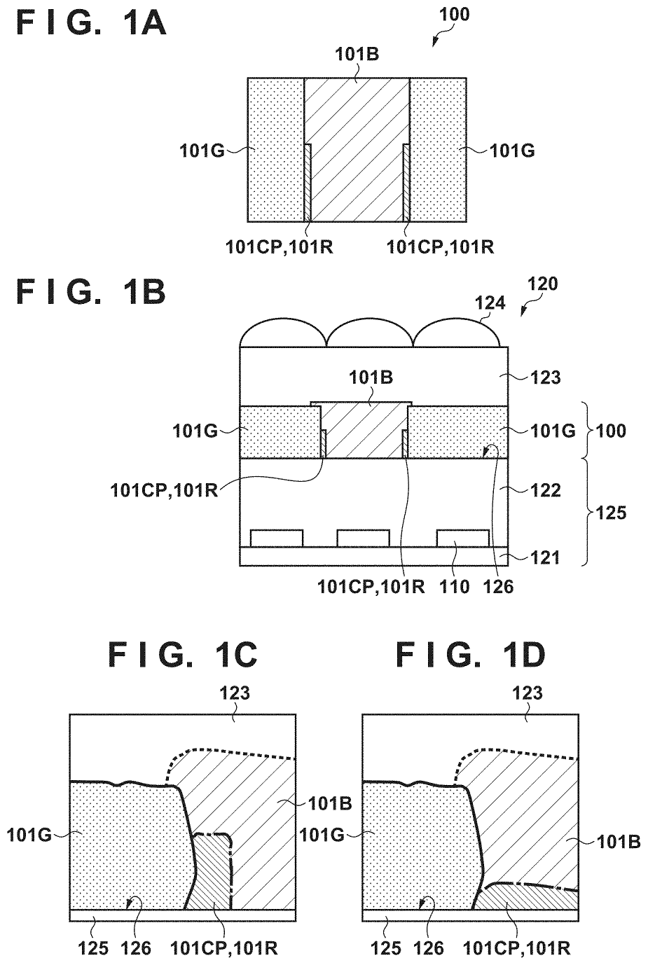

A color filter array according to an embodiment of the present disclosure will be described with reference to FIGS. 1A to 12. A color filter array includes color filters of various colors arrayed in a two-dimensional matrix to obtain color image display and color images in display apparatuses using light-emitting elements and photoelectric conversion apparatuses and image capturing apparatuses using light-receiving elements. The following will describe an example of a color filter array having filters of various colors arranged in correspondence with light-emitting elements that emit white light. The light-emitting elements may be, for example, organic EL elements. An organic EL element is a light-emitting element having a pair of electrodes and a light-emitting organic compound layer provided between the electrodes.

Some display apparatuses using organic EL elements are based on a scheme using organic EL elements that emit white light and color filters to perform color display (which scheme will be referred to as the white plus CF scheme hereinafter). The white plus CF scheme is a scheme of placing color filters differing in wavelength dispersion with respect to absorbed light in the exit direction of white light emitted from an organic EL element. For example, additive color mixing makes it possible to perform full color display by forming color filters of various colors so as to make emission colors after transmission through the color filters become red, green, and blue. A display apparatus based on the white plus CF scheme is required to suppress a deterioration in color purity which is caused when a pixel in a given color emits light and stray light exits from the color filters of adjacent pixels.

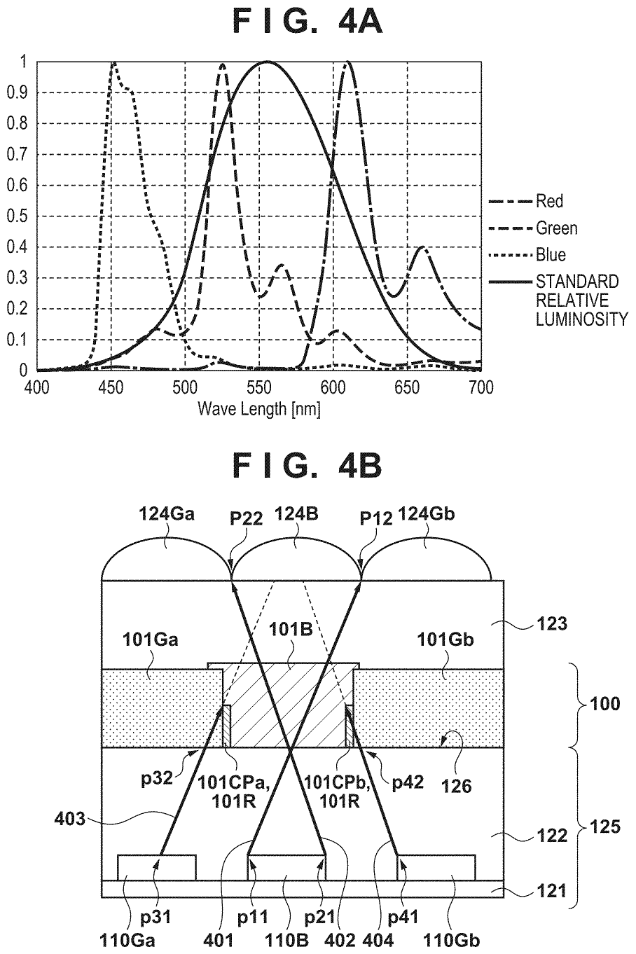

Human relative luminosity and the spectral transmittance of the color filters of the respective colors in this display apparatus will be described first. Referring to FIG. 4A, a standard relative luminosity is indicated by the solid line. This curve indicates that, assuming that the intensity of the sensitivity with which a human feels at a wavelength of 555 nm, at which the sensitivity of the human eyes is maximized upon adapting to a bright place, is “1”, the sensitivity at a blue wavelength (450 nm) is “0.038”, which is about 1/25 the sensitivity at a wavelength of 555 nm. Since this standard relative luminosity varies for each wavelength, when blue, at which the sensitivity is low, is mixed with another color at which the sensitivity is high, blue is strongly influenced by another color to cause a deterioration in color reproducibility. This further increases the necessity to prevent color mixture with respect to blue. That is, when using the white plus CF scheme, it is highly necessary to prevent light transmitted through a color filter of a color different from blue from entering a filter of blue.

FIG. 4A also shows the normalized spectra obtained after white light emitted from organic EL elements is transmitted through color filters of red, green, and blue. Among these curves, the curve of light in the blue band and the curve of light in the red band indicate that the intensities become almost zero at wavelengths of about 550 nm to 570 nm. This indicates that when light is transmitted through both a color filter for the blue band and a color filter for the red band, the amount of transmitted light is almost zero. For this reason, the necessity to take measures against light mixing in a color filter for the blue band is low concerning light transmitted through a color filter for the red band. On the other hand, it is highly necessary to take measures to prevent light transmitted through a color filter for the green band, which transmits light in the green band, from mixing in a color filter of the blue band. A light-receiving element subjected to color mixture can correct color expression by software. In contrast to this, a light-emitting element is required to improve the purity of blue color when, for example, a human observes the light-emitting element.

FIG. 1A is a sectional view showing an example of the configuration of a color filter array 100 according to this embodiment. As shown in FIG. 1A, a color filter 101B for the blue band is formed adjacent to color filters 101G for the green band. FIG. 1B is a sectional view showing an example of the configuration of an electronic device 120 including the color filter array 100 shown in FIG. 1A and light-emitting elements 110 arranged in correspondence with color filters 101 arranged in the color filter array 100. The electronic device 120 includes the light-emitting elements 110 arranged on a substrate 121, a protective layer 122 placed on the light-emitting elements 110, and the color filter array 100 placed on the protective layer 122. The electronic device 120 further includes a planarizing layer 123 placed on the color filter array 100 and microlenses 124 arranged in correspondence with the optical axes of the respective light-emitting elements 110. The electronic device 120 may be formed by sequentially forming the protective layer 122, the color filter array 100, the planarizing layer 123, and the microlenses 124 on the substrate 121. Alternatively, the electronic device 120 may be formed by bonding an array of the microlenses 124, formed separately, on the structure obtained by forming the planarizing layer 123 on the substrate 121. In this case, a structure in a step in which the protective layer 122 of the electronic device 120 is formed before the formation of the color filter array 100 is called a base member 125.

As shown in FIGS. 1A and 1B, concerning the color filters 101G and the color filter 101B, which are arranged adjacent to each other, end portions of the color filter 101B which are located alongside the color filters 101G are arranged on the color filters 101G. In other words, the end portions of the color filters 101G which are located alongside the color filter 101B are located between the end portions of the color filter 101B which are located alongside the color filter 101G and a principal surface 126 of the base member 125. In addition, spaces are arranged in the portions where the color filters 101G are in contact with the color filter 101B. Each space has an inner wall whose upper and side surfaces are constituted by the color filter 101G and the color filter 101B and whose lower surface is constituted by the principal surface 126 of the base member 125. This space is filled with a color filter 101CP formed by a color filter 101R for the red band. That is, the color filter 101R includes the color filter 101CP which is a portion placed between an end portion of the color filter 101B and the principal surface 126 of the base member 125. In addition, the end portions of the color filter 101B which are located alongside the color filters 101G and the color filters 101CP are in contact with the color filters 101G. In this case, the principal surface 126 of the base member 125 is the surface on which the color filter array 100 of the base member 125 is formed.

FIG. 1C is an enlarged sectional view showing a state in which a concave portion is formed in the lower portion of a side surface of the color filter 101B for the blue band and the color filter 101R for the red band has entered the concave portion. A method of manufacturing the color filter array 100, which includes forming the concave portions of the color filter 101B, will be described later. In addition, FIG. 1D explicitly shows the boundary lines of a color filter 101 when the actually manufactured color filter array 100 is observed with a section SEM (Scanning Electron Microscope). The SEM image in FIG. 1D indicates that the color filter 101CP using the color filter 101R for the red band having entered in the concave portion of the color filter 101B has a small (low) thickness (height). However, the shape in FIG. 1C can be formed by adjusting the amount of exposure light at the time of forming the color filter 101B for the blue band.

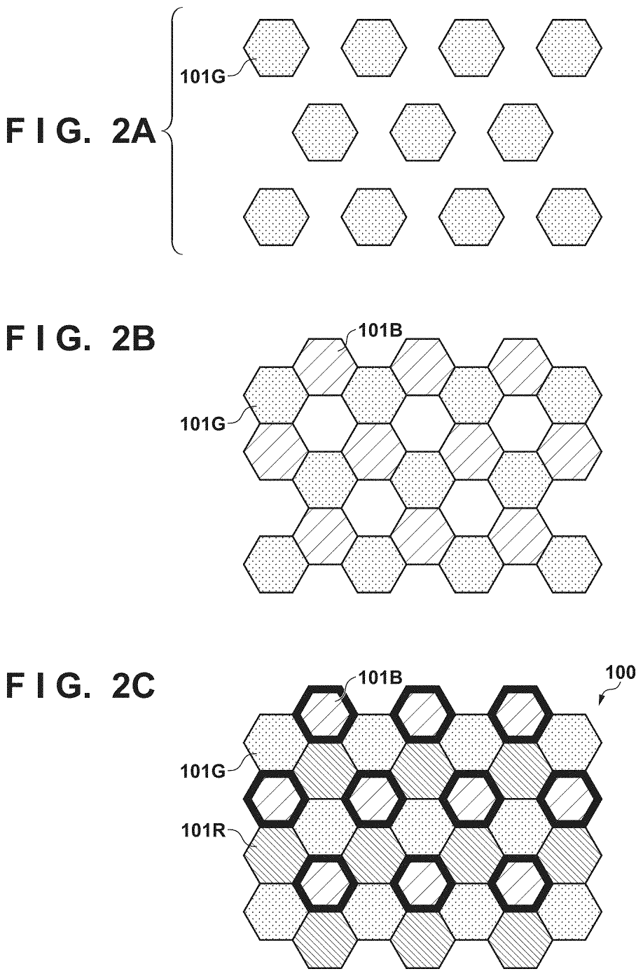

A method of manufacturing the color filter array 100 having the structure shown in FIGS. 1A to 1D will be described next. First of all, as shown in FIG. 2A, the color filters 101G for the green band are formed by using a lithography process including the coating, exposing, and developing of a photosensitive material as a material for the color filters 101G.

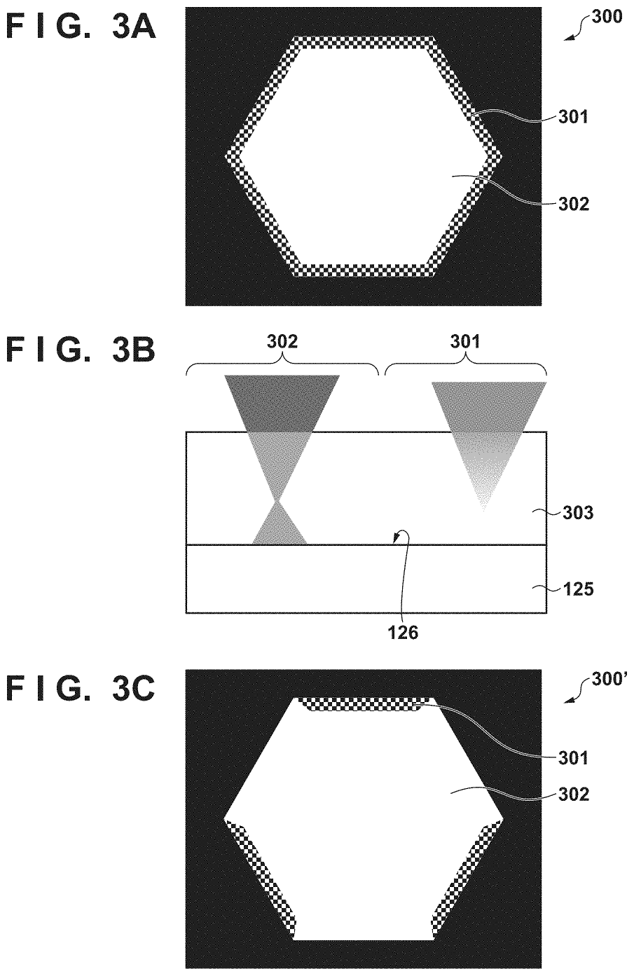

As shown in FIG. 2B, after the formation of the color filters 101G, the color filters 101B for the blue band are formed. The color filters 101B for the blue band are formed by using a negative photosensitive material. A process of forming the color filters 101B includes a step of coating with a photosensitive material as a material for the color filters 101B and an exposing step of irradiating, with light, regions of the coated photosensitive material in which the color filters 101B are formed. As shown in FIG. 3A, a reticle 300 used in this exposing step is configured such that, of the portion on which the color filter 101B is formed, an outer edge portion 301 is lower in transmittance than a central portion 302. In order to reduce the light transmittance of the outer edge portion 301, for example, a hounds-tooth check pattern as a chromium pattern is formed on the outer edge portion 301 of the portion where the color filter 101B is formed, as shown in FIG. 3A. Forming the hounds-tooth check pattern will reduce the transmittance of the outer edge portion 301 of the portion where the color filter 101B is formed to a transmittance lower than that of the central portion 302 by a value corresponding to the area of the portion where the chromium is placed. Each lattice is reduced to a pattern smaller than the resolution limit of an exposure apparatus to form, on a photosensitive material, an image whose light intensity is uniformly reduced on the outer edge portion 301 without transferring a lattice pattern. In the configuration shown in FIG. 3A, the hounds-tooth check pattern is formed on the outer edge portion 301. However, this is not exhaustive. The outer edge portion 301 of the portion of the reticle 300 on which the color filter 101B is formed may be provided with a pattern that attenuates the light transmittance of the central portion 302.

FIG. 3B is a schematic view showing a state in which the base member 125 is coated with a negative photosensitive material 303 as a material for the color filter 101B, and light is transmitted through the photosensitive material 303 at the time of exposing. With a sufficient amount of exposure light on the central portion 302, light is transmitted through the central portion 302 up to the boundary portion between the negative photosensitive material 303 and the base member 125. Since the photosensitive material is of the negative type, a photosensitive material residue is left on the portion which transmits the light after developing. On the other hand, since the lattice pattern reduces the light intensity on the outer edge portion 301, exposure light is absorbed by the resist before reaching some midpoint (for example, a middle portion) of the photosensitive material 303, and the boundary portion with the base member 125 is not exposed. That is, in an exposing step for forming the color filter 101B, the amount of exposure light in a region as an external edge portion of the color filter 101B which corresponds to the outer edge portion 301 of the reticle 300 is smaller than that in a region as a central portion of the color filter 101B which corresponds to the central portion 302 of the reticle 300. A photosensitive material is removed from an unexposed portion after developing because the photosensitive material is of the negative type.

Accordingly, as shown in FIGS. 1A to 1D, an upper portion of the color filter 101B for the blue band is overlapped on the color filter 101G for the green band. In addition, a lower portion of a side surface of the color filter 101B which is located alongside the principal surface 126 of the base member 125 is provided with a concave portion whose side surface is closer to the center of the color filter 101B than the upper portion placed above the lower portion. That is, a concave portion is formed in a lower portion of the color filter 101B to form a space in which the color filter 101B is not placed.

After the formation of the color filter 101B, the color filter 101R for the red band is formed. At this time, part of the material for the color filter 101R enters a concave portion formed in the lower portion of a side surface of the color filter 101B. That is, as shown in FIGS. 1A to 1D, the space surrounded by the color filter 101B, the color filter 101G, and the principal surface 126 of the base member 125 is filled with the color filter 101CP as part of the color filter 101R. At this time, when the color filter array 100 is observed from above, as shown in FIG. 2C, the color filter 101B is overlapped on the color filter 101CP (color filter 101R) at an outer edge portion of the color filter 101B for the blue band, and hence the outer edge portion becomes black. The color filter 101CP (color filter 101R) with which the concave portion formed in the lower portion of a side surface of the color filter 101B is filled is not removed after a lithography process including exposing and developing for the formation of the color filter 101R. This is also obvious from the SEM image observed for the plotting of FIG. 1D depicting the boundary lines of the color filter 101.

The following may be reasons why the color filter 101CP is not removed even after the lithography (exposing and developing) process for the formation of the color filter 101R. In this case, the photosensitive material used for the formation of the color filter 101R for the red band is of the negative type. One reason may be that the photosensitive material used for the color filter 101R for the read region is high in sensitivity, and hence even its portion placed under the color filter 101B is sufficiently exposed. Another reason may be that, as shown in FIGS. 1A to 1D, the photosensitive material for the color filter 101R enters the small space surrounded by the color filter 101B, the color filter 101G, and the principal surface 126 of the base member 125, and hence a developer has difficulty in reaching. As a result, even when the photosensitive material for the color filter 101R is not exposed, the color filter 101CP (color filter 101R) may be left without being developed. In addition, a sufficient amount of exposure light may reach the photosensitive material for the color filter 101R placed under the color filter 101B due to a bleaching phenomenon.

Effects of this embodiment will be described next with reference to FIG. 4B. Assume that the light-emitting element 110, the protective layer 122, the color filter array 100, the planarizing layer 123, and the microlens 124 of the electronic device 120 in FIG. 4B have the same configurations as those shown in FIG. 1B.

A light beam that enters the color filter 101B for the blue band shown in the center of FIG. 4B at the largest incidence angle is a light beam 401 that exits from a position P11 on an end portion of a light-emitting element 110B and is transmitted through a position P12 on an end portion of a microlens 124B. Likewise, a light beam that enters the color filter 101B for the blue band at the largest incidence angle is a light beam 402 that is transmitted through a position P21 on an end portion of the light-emitting element 110B located on the opposite side to the light beam 401 and a position P22 on an end portion of the microlens 124B.

Among the light beams emitted from light-emitting elements 110G adjacent to the light-emitting element 110B and transmitted through the color filters 101G for the green band, light beams parallel to the light beams 401 and 402 can enter the microlens 124b and mix with each other. For example, as shown in FIG. 4B, consider a light beam 403 that is emitted from a light-emitting element 110Ga and parallel to the light beam 401. The light beam 403 that exits from a position P31 on the light-emitting element 110Ga and is transmitted through a position P32 on a color filter 101Ga is blocked by a color filter 101CPa formed from the same material as that for the color filter 101R for the red band and suppressed from entering the color filter 101B. Likewise, consider a light beam 404 that is emitted from a light-emitting element 110Gb and parallel to the light beam 402. The light beam 404 that exits from a position P41 on the light-emitting element 110Gg and is transmitted through a position P42 on the color filter 101Gb is blocked by a color filter 101CPb formed from the same material as that for the color filter 101R for the red band and suppressed from entering the color filter 101B. This can prevent a deterioration in color purity caused when a light beam transmitted through the color filter 101G with high relative luminosity passes through the adjacent color filter 101B between the adjacent pixels. The width and height of the color filter 101CP may be adjusted as appropriate in accordance with the positions and intervals at which the light-emitting elements 110 are arranged, the thicknesses of the protective layer 122, the color filter 101, and the planarizing layer 123, and the like.

The reticle 300 shown in FIG. 3A is configured such that the whole outer edge portion 301 of the portion where the color filter 101B is formed is lower in light transmittance than the central portion 302. However, this is not exhaustive. As described above, the color filter 101CP using the same material as that for the color filter 101B is formed in a portion where the color filter 101G is adjacent to the color filter 101B to suppress a deterioration in color purity. Accordingly, as shown in FIG. 3C, only a portion of the outer edge portion 301 which is in contact with the color filter 101G may be configured to be lower in light transmittance than the central portion 302. A reticle 300′ shown in FIG. 3C includes the outer edge portion 301 whose light transmittance is reduced in only a portion in contact with the color filter 101G for the green band.

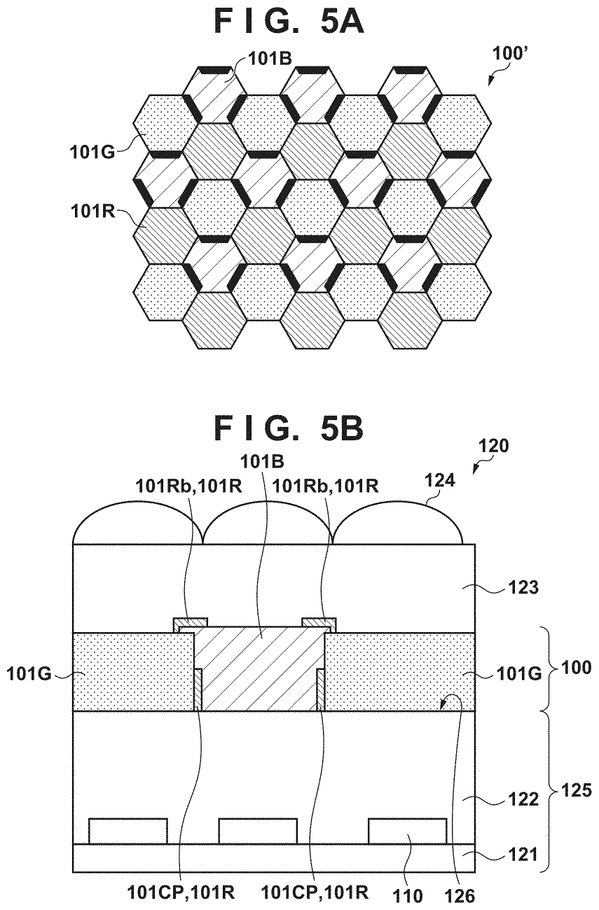

FIG. 5A is a plan view of a color filter array 100′, observed from above, which is manufactured by using the reticle 300′ shown in FIG. 3C. When compared with the color filter array 100 manufactured by using the reticle 300 shown in FIG. 2C, only a portion where the upper portion of a side surface of the color filter 101G for the green band is in contact with that of the color filter 101B for the blue band is observed as being black.

When the reticle 300′ shown in FIG. 3C is used, there is no concave portion in a lower portion of a side surface of the color filter 101B, where the color filter 101B for the blue band is in contact with the color filter 101R for the red band. This increases the contact surface of the color filter 101B with respect to the base member 125 and thus increases the stability of the color filter 101B. More specifically, as the contact area of the color filter 101B with respect to the base member 125 decreases, the color filter 101B may fall or move from a predetermined position after the formation of the color filter 101B. Increasing the contact area of the color filter 101B with respect to the base member 125 can suppress a decrease in yield when the color filter array 100 is manufactured. In addition, since no concave portion is formed in a portion of the color filter 101B which is in contact with the color filter 101R, the size of the concave portion in a portion of the color filter 101B which is in contact with the color filter 101G may be increased accordingly. This makes it possible to provide characteristics advantageous in improving both the color reproducibility and yield.

In addition, in order to further improve the color reproducibility by suppressing a deterioration in color purity, the electronic device 120 may include the color filter array 100 shown in FIG. 5B. More specifically, a color filter 101Rb using the same material as that for the color filter 101R may be further formed on a portion (end portion) where the color filter 101G is overlapped on the color filter 101B. For example, when the color filter 101R is formed, the color filter 101Rb shown in FIG. 5B can be manufactured by patterning the material for the color filter 101R so as to leave the material on a portion where the color filter 101G is in contact with the color filter 101B. The structure shown in FIG. 5B can be applied to an electronic device giving priority to color reproducibility although having a problem of worsening the flatness of the upper portion of the color filter array 100.

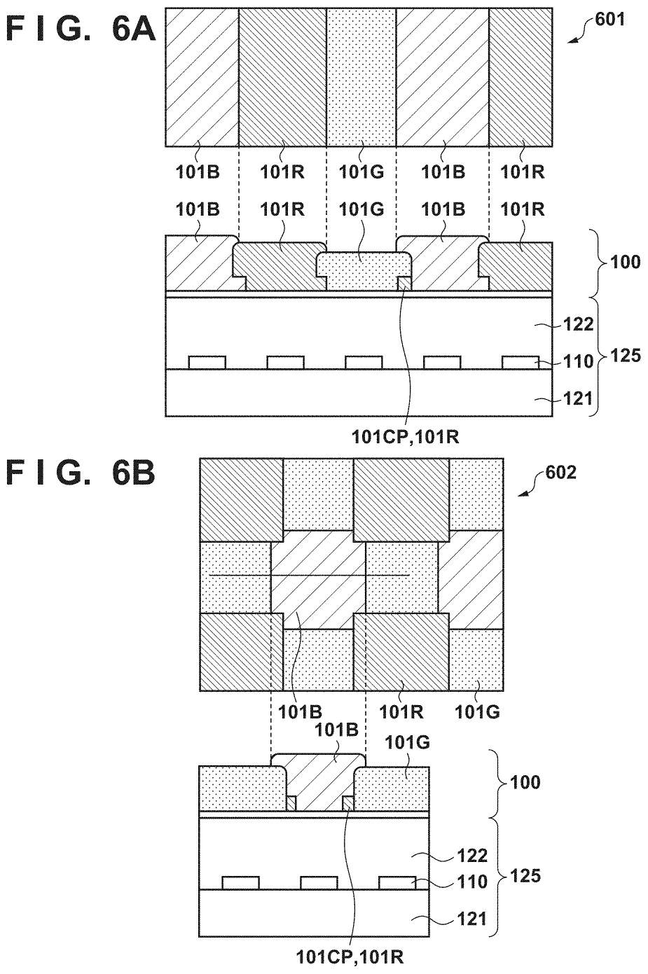

The above embodiment has been described on the assumption that the color filter 101 has a hexagonal shape, as shown in FIG. 2A. However, the shape of the color filter 101 is not limited to a hexagonal shape. For example, as shown in FIG. 6A, the configurations of the above embodiment may be applied to a color filter array 601 having a stripe shape. For example, as shown in FIG. 6B, the configuration of the above embodiment may be applied to a color filter array 602 having a rectangular shape. In addition, the above embodiment has been described on the assumption that the color filters 101 are arranged in a delta arrangement, as shown in FIG. 2A. However, the arrangement of the color filters 101 is not limited to a delta arrangement. For example, the configurations of the above embodiment may be applied to the color filter array 602 arranged in a Bayer arrangement. In addition, the configurations of the above embodiment may be applied to the color filter array 602 arranged in a diagonal arrangement or to the color filter array 602 arranged in a pentile arrangement.

According to the embodiment described above, the color filter 101G, the color filter 101B, and the color filter 101R are formed in this order. However, this is not exhaustive. The configuration shown in FIG. 6A indicates a case in which the color filter 101G, the color filter 101R, and the color filter 101B are formed in this order. That is, at an end portion of each color filter 101, the color filter 101B and the color filter 101R are arranged on the color filter 101G, and the color filter 101B is placed on the color filter 101R. In this case, the color filter 101G is formed so as to form a concave portion in the lower portion of a side surface of the color filter 101G. Accordingly, in the structure shown in FIGS. 1A to 1D, the upper surface of the color filter 101CP is covered with the color filter 101B. In the structure shown in FIG. 6A, the upper surface of the color filter 101CP is covered with the color filter 101G. That is, an end portion of the color filter 101G is located between an end portion of the color filter 101R and the principal surface 126 of the base member 125. In addition, the color filter 101R includes a portion placed between an end portion of the color filter 101G which is located alongside the color filter 101R and the principal surface 126 of the base member 125.

In the configuration shown in FIG. 6B, as described with reference to FIGS. 1A to 3C, the color filter 101G, the color filter 101B, and the color filter 101R are formed in this order. Accordingly, as shown in FIG. 6B, at an end portion with which each color filter 101 is in contact, the color filter 101B and the color filter 101R are arranged on the color filter 101G, and the color filter 101R is placed on the color filter 101B. That is, an end portion of the color filter 101G which is located alongside the color filter 101B is located between an end portion of the color filter 101B and the principal surface 126 of the base member 125.

In the case shown in FIG. 6A as well, at a portion where the color filter 101G is in contact with the color filter 101B so as to be arranged adjacent to each other, a color filter CP is placed in the space surrounded by the color filter 101G, the color filter 101B, and the base member 125. This further suppresses light transmitted through the color filter 101G from passing through and exiting from the color filter 101B and thus suppresses a deterioration in color purity and improves the color reproducibility.

Alternatively, at a portion where the color filter 101G and the color filter 101R are arranged adjacent to each other, a concave portion may be formed in the lower portion of a side surface of the color filter 101G as shown in FIG. 6A as in the case shown in FIG. 2C. In other words, an end portion of the color filter 101R which is in contact with the color filter 101G may include a portion placed on the color filter 101R and a portion placed between the color filter 101G and the principal surface 126 of the base member 125. Alternatively, at a portion where the color filter 101G and the color filter 101R are arranged adjacent to each other, no concave portion may be formed in the lower portion of a side surface of the color filter 101G as in the case shown in FIG. 5A described above.

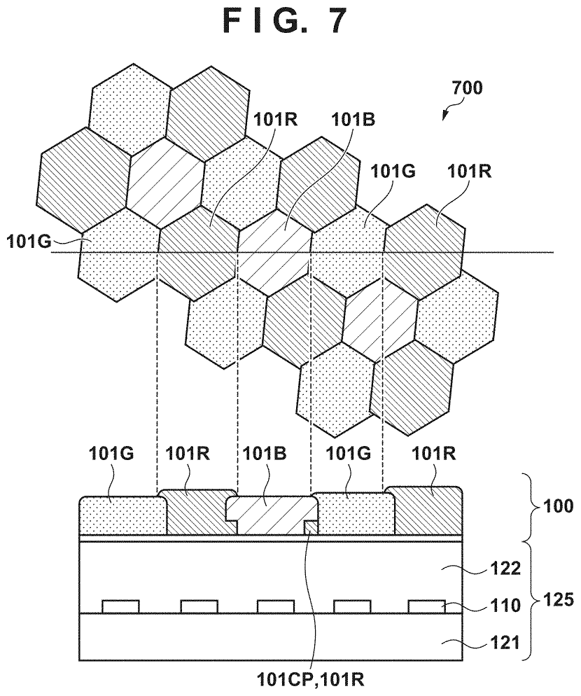

The configuration of a color filter array 700 shown in FIG. 7 indicates a case in which the color filter 101B, the color filter 101G, and the color filter 101R are formed in this order. That is, at a portion with which each color filter 101 is in contact, the color filter 101G is placed on the color filter 101B, and the color filter 101R is placed on the color filter 101G. In other words, an end portion of the color filter 101B which is located alongside the color filter 101G is located between an end portion of the color filter 101G and the principal surface 126 of the base member 125. In addition, an end portion of the color filter 101B is located between an end portion of the color filter 101R and the principal surface 126 of the base member 125, and the color filter 101R includes a portion placed between an end portion of the color filter 101B which is located alongside the color filter 101R and the principal surface 126 of the base member 125. In addition, an end portion of the color filter 101G which is located alongside the color filter 101R is located between an end portion of the color filter 101G and the principal surface 126 of the base member 125.

In this case, the color filter 101B is formed so as to form a concave portion in the lower portion of a side surface of the color filter 101B. Accordingly, in the structure shown in FIG. 7, the upper surface of the color filter 101CP is covered with the color filter 101B. Even when the color filter 101G, the color filter 101R, and the color filter 101B are formed in this order, light transmitted through the color filter 101G is suppressed from passing through and exiting from the color filter 101B. That is, even the configuration shown in FIG. 7 can suppress a deterioration in color purity and improve the color reproducibility. In this case, although it is necessary to form a concave portion in the lower portion of the color filter 101G, the above effects can be implemented by using the process described with reference to FIGS. 3A and 3B.

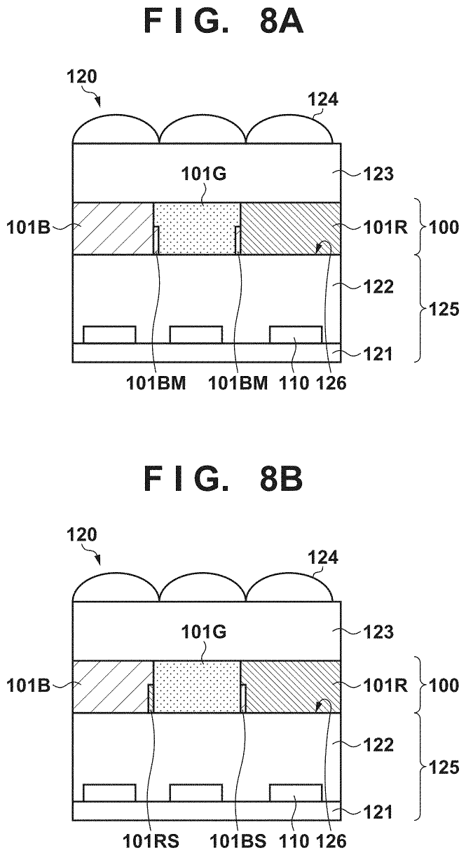

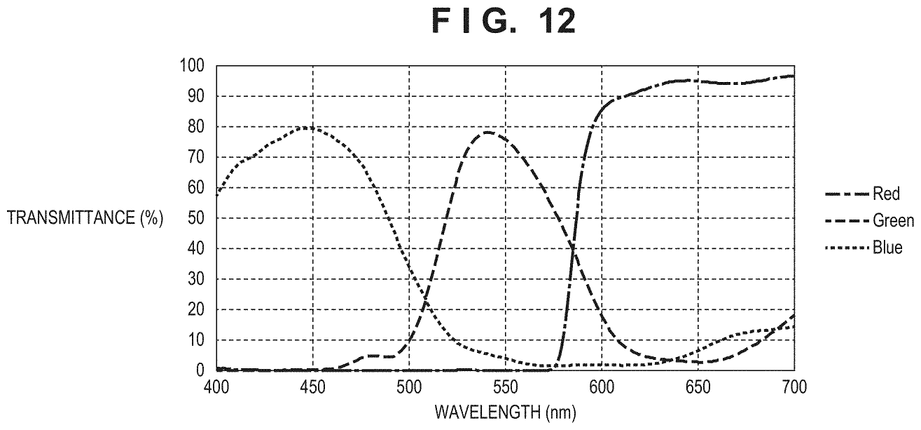

A modification of the color filter array 100 described above will be further described next with reference to FIGS. 8A to 12. FIG. 12 shows the spectral transmittances of the respective color filters for red, green, and blue. FIG. 12 shows the transmittances of the respective color filters for each wavelength of light. This indicates that each color filter transmits light in a wavelength region in which the transmittance is not 0%. Consider the visible light region (400 nm to 760 nm) in this case. As shown in FIG. 12, the wavelength region of light in which the transmittance of a color filter for the green band is 5% or more is overlapped on the wavelength region of light in which the transmittance of a color filter for the blue band is 5% or more. This indicates that when a color filter for the blue band is irradiated with white light that is applied to and transmitted through a color filter for the green band, some light is transmitted through the filter in the visible light region. Likewise, the wavelength region of light in which the transmittance of a color filter for the green band is 5% or more is overlapped on the wavelength region of light in which the transmittance of a color filter for the red band is 5% or more. This indicates that when a color filter for the red band is irradiated with white light applied to and transmitted through a color filter for the green band, some light is transmitted through the filter in the visible light region. In contrast to this, the wavelength region of light in which the transmittance of a color filter for the blue band is 5% or more is hardly overlapped on the wavelength region of light in which the transmittance of a color filter for the red band is 5% or more. More specifically, in the case shown in FIG. 12, the wavelength region of light in which the transmittance of a color filter for the blue band is 5% or more is about 400 nm to 550 nm, and the wavelength region of light in which the transmittance of a color filter for the red band is 5% or more is about 575 nm to 700 nm. The two wavelength regions are not overlapped on each other.

Accordingly, light transmitted through both a color filter for the green band and a color filter for the blue band differs in color from light transmitted through only one of the color filters, and hence causes the problem of color mixture. Likewise, light transmitted through both a color filter for the green band and a color filter for the red band differs in color from light transmitted through only one of the color filters, and hence causes the problem of color mixture. In contrast to this, light transmitted through both a color filter for the blue band and a color filter for the red band is hardly transmitted through the entire visible light region, and hence hardly causes the problem of color mixture (although a slight amount of light can be transmitted through the region). That is, the necessity to take measures for mixing of colors due to light transmitted through color filters for the green and blue bands and light transmitted through color filters for the green and red bands is higher than for light transmitted through color filters for the blue and red.

In this embodiment, therefore, light-shielding members are selectively arranged between two types of color filters that easily cause color mixture in the color filter array 100 including the first color filters, the second color filters, and the third color filters that are arranged on the base member 125 and different in color from each other. More specifically, assume that the wavelength region of light in which a first color filter has a spectral transmittance of 5% or more in the visible light region is a first wavelength region, the wavelength region of light in which a second color filter has a spectral transmittance of 5% or more in the visible light region is a second wavelength region, and the wavelength region of light in which a third color filter has a spectral transmittance of 5% or more in the visible light region is a third wavelength region. A wavelength region where the first wavelength region overlaps the third wavelength region is narrower than a wavelength region where the first wavelength region overlaps the second wavelength region and a wavelength region where the second wavelength region overlaps the third wavelength region. In this case, the light shielding effect of the boundary region between the first color filter and the second color filter and between the second color filter and the third color filter is made higher than the light shielding effect of the boundary region between the first color filter and the third color filter. For example, light-shielding members may be selectively arranged only between the boundary regions between the first color filters and the second color filters and between the boundary regions between the second color filters and the third color filters. More specifically, light-shielding members may be selectively arranged only between the color filters 101G for the green band and the color filters 101R for the red band and between the color filters 101B for the blue band and the color filters 101G for the green band. In addition, any light-shielding members may need not be selectively arranged only between the color filters 101R for the red band and the color filters 101B for the blue band. In this case, in the color filter array 100, considering three types of members, namely the first color filter, the second color filter, and the third color filter, a boundary region is a region where two color filters are adjacent to each other without sandwiching the other color filter.

FIG. 8A is a sectional view showing an example of the configuration of the electronic device 120 including the color filter array 100 according to this embodiment and the light-emitting elements 110 arranged in correspondence with the respective color filters 101 arranged in the color filter array 100. Each embodiment described above is provided with a space having an inner wall whose upper and side surfaces are constituted by the color filter 101G and the color filter 101B and whose lower surface is constituted by the principal surface 126 of the base member 125. This space is filled with the color filter 101CP formed from the color filter 101R. Unlike in each embodiment described above, in the configuration shown in FIG. 8A, a color filter 101BM is placed as a light-shielding member for the prevention of color mixture in this space. In addition, this embodiment is provided with a space having an inner wall whose upper and side surfaces are constituted by the color filter 101G and the color filter 101R and whose lower surface is constituted by the principal surface 126 of the base member 125. The color filter 101BM for the prevention of color mixture is placed in this space. Other configurations may be the same as those of the electronic device 120 shown in FIG. 1B, and hence a description will be omitted.

For example, the color filter 101BM for the prevention of color mixture may be a resin layer formed by using a resist including a pigment or dye for the prevention of transmission of light such as black light. In addition, for example, a metal layer using a metal such as aluminum or chromium or its alloy may be used as a light-shielding member instead of the color filter 101BM. As shown in FIG. 8A, placing the color filters 101BM between color filters for the green and blue bands and between color filters for the green and red bands can suppress color mixture and improve the color purity. Furthermore, in orthogonal projection with respect to the principal surface 126 of the base member 125, the color filter 101BM as a light-shielding member for suppressing color mixture may be placed to surround the color filter 101G for the green band. In this case, the color filter 101BM may or may not be provided between the color filters 101B and 101R for the blue and red bands.

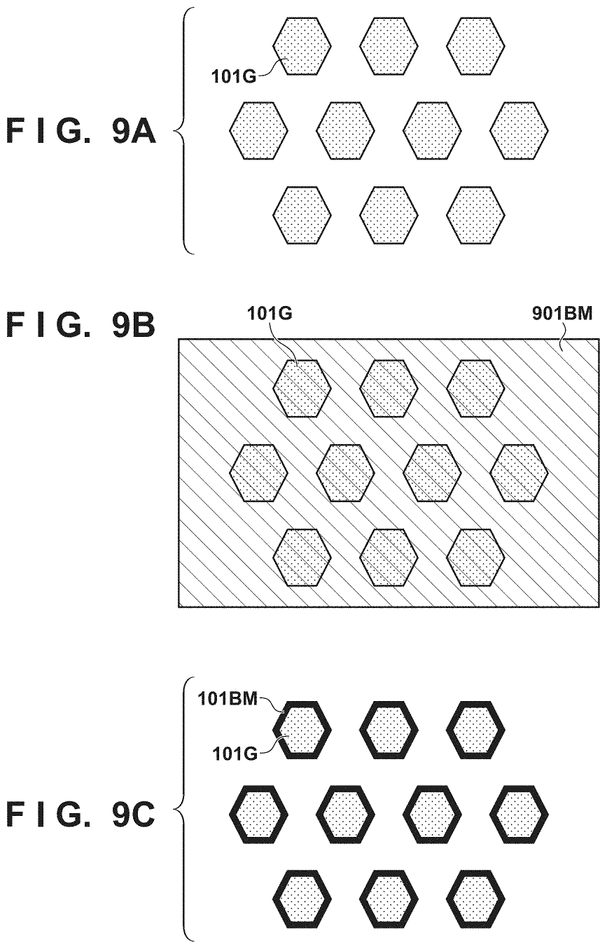

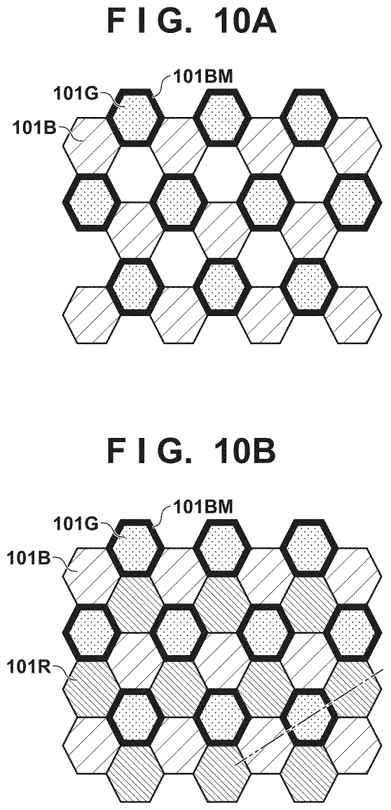

A method of manufacturing the color filter array 100 shown in FIG. 8A will be described next with reference to FIGS. 9A to 10B. First of all, as shown in FIG. 9A, the color filter 101G for the green band is formed by using a lithography process including the coating, exposing, and developing of a photosensitive material as a material for the color filters 101G. The color filter 101G for the green band is formed by using, for example, a negative photosensitive material. In the lithography process, for example, the color filter 101G after developing has an overhang shape at each end portion, as shown in FIG. 8A, by, for example, controlling the amount of exposure light and focus position of an exposure apparatus and controlling the transmittance of the pattern of the reticle 300 described above.

After the formation of the color filter 101G, a color filter 101BM for the prevention of color mixture is formed. First of all, as shown in FIG. 9B, for example, a black resist 901BM as a material for the color filter 101BM is deposited by spin coating. Although not explicitly shown in FIG. 9B, the base member 125 can be coated with the black resist 901BM in a liquid state with high fluidity. Accordingly, the black resist 901BM also enters a lower concave portion of the color filter 101G which has an overhang shape. As the black resist 901BM, for example, a material can be used, which has a spectral transmittance of 5% or less in the visible light region at the film thickness of the residue in the concave portion formed by the overhang shape of the color filter 101G.

As shown in FIG. 9C, the color filter 101BM is formed by removing the black resist 901BM placed outside the concave portion formed by the overhang shape of the color filter 101G. For example, anisotropic etching using 02 plasma can be used for etching the black resist 901BM.

After the formation of the color filter 101BM for the prevention of color mixture, the color filter 101B for the blue band is formed, as shown in FIG. 10A. In addition, as shown in FIG. 10B, the color filter 101R for the red band is formed. The color filter 101B for the blue band and the color filter 101R for the red band can be formed by, for example, a lithography process using a negative photosensitive material. The color filter array 100 like that shown in FIG. 8A can be formed by a process including the above processes. In this case, the color filter 101R for the red band is formed after the formation of the color filter 101B for the blue band. However, the color filter 101B for the blue band may be formed after the formation of the color filter 101R for the red band.

In this embodiment, the color filter 101BM for the prevention of color mixture is left only in the concave portion formed in an end portion of the pattern of the color filter 101G for the green band. For this reason, when the color filter array 100 is observed from above, the outer edge portion of each color filter 101G for the green band is colored in black by the color filter 101BM, as shown in FIG. 10B. A section of the portion indicated by the dotted line of FIG. 10B corresponds to FIG. 8A.

In this embodiment, only the outer edge portion of each color filter 101G for the green band is colored in black by using the color filter 101BM. This configuration is especially highly effective for a display apparatus using light-emitting elements, for example, organic EL elements. Since light in the green band has a high luminosity factor, color mixture of light in the blue and red bands will greatly degrade the color purity. On the other hand, in order to increase the luminance, it is effective to ensure a light-emitting region as much as possible. Forming a color mixture preventing structure using the color filter 101BM (for example, a black resist) around only the color filter 101G for the green band can satisfy both requirements concerning color purity and luminance, and is effective.

In the case shown in FIGS. 9A to 10B, the color filter 101BM for the prevention of color mixture is formed after the formation of the color filter 101G for the green band. However, this is not exhaustive. As described above, a metal may be used as a light-shielding member for the prevention of color mixture. In addition, the formation of a light-shielding member is not limited to after the formation of the color filter 101G for the green band.

For example, first of all, the color filter 101B for the blue band and the color filter 101R for the red band are formed in an appropriate order. A light-shielding member for the prevention of color mixture is then formed. For example, as in the above case, the black resist 901BM serving as a material for the color filter 101BM is formed by spin coating. Thereafter, the black resist 901BM may be etched so as to leave the outer edge portion of a portion on which the color filter 101G for the green band is formed, thereby forming the color filter 101BM as a light-shielding member for the prevention of color mixture. In addition, for example, after the formation of the color filters 101B and 101R for the blue and red bands, a metal layer is formed on the base member 125. Subsequently, a light-shielding member may be formed by etching the metal layer so as to leave the metal layer on the outer edge portion of the portion on which the color filter 101G for the green band is formed. After the formation of the light-shielding member for the prevention of color mixture, the color filter 101G for the green band is formed, thereby forming the color filter array 100 shown in FIG. 8A.

In addition, for example, first of all, a light-shielding member for the prevention of color mixture is formed in a region serving as the outer edge portion of the color filter 101G for the green band on the base member 125. A light-shielding member can be formed by using an appropriate process like that described above. Since a light-shielding member can be formed before the formation of the color filter 101 of each color, it is possible to increase the number of choices concerning a material for a light-shielding member and the number of choices concerning a process for formation as compared with a case in which a light-shielding member is formed after the formation of each color filter 101. After the formation of the light-shielding member, the color filter 101G for the green band is formed. In this case, the color filter 101G may be formed higher than a light-shielding member and etched to have a predetermined height. After the formation of the color filter 101G for the green band, the color filters 101B and 101R for the blue and red bands are formed in an appropriate order.

In addition, for example, first of all, the color filters 101G, 101B, and 101R for the green, blue, and red bands are formed in an appropriate order. Subsequently, the portions of the color filters 101G, 101B, and 101R which are in contact with the outer edge portion of the color filter 101G for the green band are etched to the base member 125. At this time, any one of the color filters 101G, 101B, and 101R may be etched. Subsequently, a material for a light-shielding member for the prevention of color mixture may be embedded in the etched portion of the outer edge portion of the color filter 101G. For example, the black resist 901BM serving as a material for the color filter 101BM may be deposited by spin coating, and a metal layer may be deposited by using a sputtering method. A light-shielding member like that shown in FIG. 8A is then formed by removing the material for the light-shielding member except for the portion placed on the outer edge portion of the color filter 101G.

In the configuration shown in FIG. 8A, the upper, side, and lower surfaces of the color filter 101BM as a light-shielding member for the prevention of color mixture are covered with the base member 125, the color filter 101G, the color filter 101B, and the color filter 101R. However, this is not exhaustive. The upper surface of the light-shielding member for the prevention of color mixture may be partly or entirely exposed without being covered with the color filters 101G, 101B, and 101R. In other words, a light-shielding member such as the color filter 101BM may be in contact with the planarizing layer 123. For example, in using the process of embedding the material serving as the light-shielding member in the etched portion of the outer edge portion of the color filter 101G described above, at least part of the upper surface of the light-shielding member can be exposed without being covered with the color filters 101G, 101B, and 101R. In this case, in an orthogonal projection on the principal surface 126 of the base member 125, a light-shielding member such as the color filter 101BM does not need to be overlapped on another color filter 101 such as the color filter 101G.

In addition, a light-shielding member for the prevention of color mixture is not limited to a material other than the color filters 101G, 101B, and 101R like the color filter 101BM or a metal layer. As shown in FIG. 12, light transmitted through the color filter 101B for the blue band and the color filter 101R for the red band is hardly transmitted in a visible light region. Accordingly, as shown in FIG. 8B, the color filter 101R may be placed on the portion where end portions of the color filter 101G and the color filter 101B are in contact with each other. In other words, the portion where the color filter 101G is in contact with the color filter 101B is provided with a space having an inner wall whose upper and side surfaces are constituted by the color filter 101G and the color filter 101B and whose lower surface is constituted by the principal surface 126 of the base member 125. This space is filled with a color filter 101RS formed from the color filter 101R for the red band. Likewise, the color filter 101B may be placed on the portion where end portions of the color filter 101G and the color filter 101R are in contact with each other. In other words, the portion where the color filter 101G is in contact with the color filter 101R is provided with a space having an inner wall whose upper and side surfaces are constituted by the color filter 101G and the color filter 101R and whose lower surface is constituted by the principal surface 126 of the base member 125. This space is filled with a color filter 101BS formed from the color filter 101B for the red band. This makes it unnecessary to prepare any material other than the color filters 101G, 101B, and 101R. For example, it is possible to reduce a cost for manufacturing the color filter array 100.

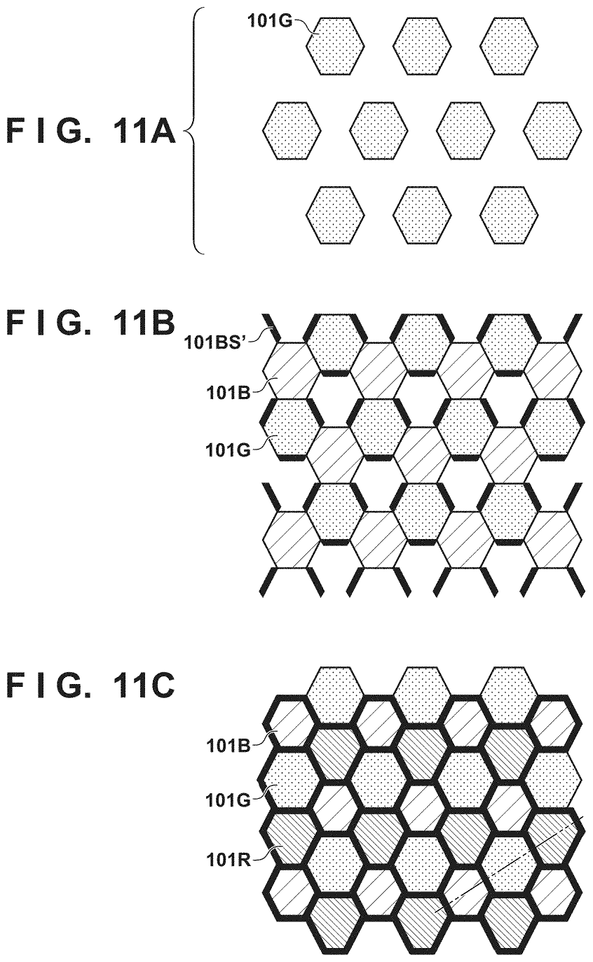

A method of manufacturing the color filter array 100 shown in FIG. 8B will be described next with reference to FIGS. 11A to 11C. As shown in FIG. 11A, the color filters 101G for the green band are formed by using a lithography process including the coating, exposing, and developing of a photosensitive material as a material for the color filters 101G. The color filters 101G for the green band are formed by using, for example, a negative photosensitive material.

As shown in FIG. 11B, after the formation of the color filters 101G, the color filters 101B and 101BS for the blue band are formed by using a lithography process. The color filters 101B and 101BS are formed by using, for example, a negative photosensitive matter. In the lithography process, for example, the color filter 101B after developing can have overhang shapes at end portions, as shown in FIG. 8B, by controlling the amount of exposure light and focus position of an exposure apparatus, controlling the transmittance of the pattern of the reticle 300 described above, and the like. In addition, the color filter 101BS is formed to have a thickness smaller than that of the color filter 101B.

As shown in FIG. 11C, the color filters 101R for the red band are then formed. The base member 125 can be coated with a material for the color filters 101R in a liquid state with high fluidity. Accordingly, the material for the color filters 101R also enters lower concave portions of the color filters 101B which have overhang shapes, thereby forming the color filters 101RS. The color filters 101R are also formed on the color filters 101BS. Wavelengths with high transmittance from the color filter 101B for the blue band and the color filter 101R for the red band hardly overlap each other in the optical spectrum shown in FIG. 12. For this reason, when the color filter array 100 is observed from above, only the boundary portions between the color filters 101 become black, as shown in FIG. 11C. A section of the portion indicated by the dotted line of FIG. 11C corresponds to FIG. 8B. This structure can also suppress color mixture and a deterioration in color purity.

In order to improve the luminance, a reflecting layer may be placed between the substrate 121 and the light-emitting elements 110. FIG. 1B shows that the light-emitting elements 110 are in contact with the upper surface of the substrate 121. In practice, however, elements such as transistors can be formed on the surface of the substrate 121, one or more interlayer films in which wiring patterns and the like are formed can be formed on the elements, and the light-emitting elements 110 can be formed on the interlayer films. For this reason, when, for example, the electrodes on the substrate 121 side of the light-emitting elements 110 are transparent electrodes, light emitted from the light-emitting elements 110 can propagate in the direction of the substrate 121. Accordingly, placing a reflecting layer between the substrate 121 and the light-emitting elements 110 can improve the usage efficiency of light emitted from the light-emitting elements 110 and increase the luminance. The reflecting layer may be formed by using, for example, a metal such as aluminum, copper, titanium, chromium, or tungsten or one of their alloys. Alternatively, for example, part of the above wiring pattern may be used as a reflecting layer.

When a reflecting layer is provided between the substrate 121 and the light-emitting elements 110, members for light shielding may be placed in an interlayer film between the light-emitting elements 110 and the reflecting layer in accordance with the positions of the respective color filters 101. For example, in orthogonal projection with respect to the principal surface 126 of the base member 125, members for light shielding may be placed at positions to overlap the outer edges of the respective color filters 101. The members for light shielding may be formed by using, for example, a metal such as aluminum, copper, titanium, chromium, or tungsten or one of their alloys. For example, vias for providing conduction between wiring patterns arranged on different layers may be used as members for light shielding.

In addition, the above embodiment has exemplified that the color filter array 100 is formed on the base member 125 on which the protective layer 122 is formed. However, this is not exhaustive. For example, the color filter array 100 having the above configuration is formed on a support substrate different from the substrate 121. The electronic device 120 may then be formed by bonding the color filter array 100 formed on the support substrate onto the base member 125 on which the light-emitting elements 110 are formed. As the support substrate, for example, a transparent substate such as a plastic or glass substrate that transmits light in the visible light region may be used. In this case, after the base member 125 is bonded to the color filter array 100, the support substate may or may not be removed. Alternatively, for example, an opaque substate such as a silicon substate may be used as the support substrate. In this case, after the base member 125 is bonded to the color filter array 100, the support substrate can be removed. When the base member 125 is bonded to the color filter array 100, a bonding layer such as an adhesive layer may be placed between the protective layer 122 on the base member 125 and the color filter array 100. The bonding layer may be, for example, a transparent resin layer that transmits light in the visible light region.

The color filter array 100 described above can be applied to both an electronic device including light-receiving elements and an electronic device including light-emitting elements, and can suppress color mixture between the color filters 101. An electronic device can include at least light-emitting elements or light-receiving elements arranged in correspondence with the color filters 101 arranged on the color filter array 100. The electronic device may include both light-emitting elements and light-receiving elements. As in the embodiment described above, when the color filter array 100 is applied to the electronic device 120 including the light-emitting elements 110, since emitted light is observed by a human without using photoelectric conversion elements, correction using software cannot be performed. Therefore, using the color filter array 100 according to this embodiment can provide an electronic device including light-emitting elements with good color reproducibility.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2020-061116, filed Mar. 30, 2020, and No. 2020-210593, filed Dec. 18, 2020 hereby incorporated by reference herein in their entirety.

What is claimed is:

1. A color filter array comprising a first color filter, a second color filter, and a third color filter that are arranged on a base member and respectively have different colors,
wherein the first color filter and the third color filter are arranged adjacent to each other,
the second color filter includes a portion placed between an end portion of the third color filter and the base member, and
the end portion of the third color filter and the portion of the second color filter are in contact with the first color filter.

2. The array according to claim 1, wherein an upper surface of the portion of the second color filter is covered with the first color filter.

3. The array according to claim 1, wherein an upper surface of the portion of the second color filter is covered with the third color filter.

4. The array according to claim 1, wherein a fourth color filter having the same color as that of the second color filter is further arranged on the base member,
the fourth color filter and the first color filter are arranged adjacent to each other, and
an end portion of the first color filter which is located alongside the fourth color filter has a portion placed between an end portion of the fourth color filter and the base member.

5. The array according to claim 4, wherein an end portion of the fourth color filter which is located alongside the first color filter has a portion placed between an end portion of the first color filter and the base member.

6. The array according to claim 5, further comprising a portion where the third color filter is in contact with the fourth color filter,
wherein an end portion of the third color filter which is located alongside the fourth color filter has a portion placed between an end portion of the fourth color filter and the base member.

7. The array according to claim 1, wherein the first color filter is a color filter that transmits light in a blue band, the second color filter is a color filter that transmits light in a red band, and the third color filter is a color filter that transmits light in a green band.

8. The array according to claim 1, wherein the first color filter is a color filter that transmits light in a green band, the second color filter is a color filter that transmits light in a red band, and the third color filter is a color filter that transmits light in a blue band.

9. The array according to claim 6, wherein the first color filter is a color filter that transmits light in a green band, the second color filter is a color filter that transmits light in a red band, and the third color filter is a color filter that transmits light in a blue band.

10. An electronic device comprising a color filter array according to claim 1 and at least one of a light-emitting element and a light-receiving element that are arranged in correspondence with each color filter arranged on the color filter array.

11. The device according to claim 10, further comprising a microlens corresponding to optical axes of at least one of the light-emitting element and the light-receiving element.

12. A color filter array comprising a first color filter, a second color filter, and a third color filter that are arranged on a base member and respectively transmit light in a blue band, light in a green band, and a light in a red band, wherein the color filter array comprises:
a first boundary region where the first color filter is adjacent to the third color filter;
a second boundary region where the first color filter is adjacent to the second color filter; and
a third boundary region where the second color filter is adjacent to the third color filter,
wherein a light-shielding effect of the second boundary region and a light-shielding effect of the third boundary region are higher than a light-shielding effect of the first boundary region.

13. The array according to claim 12, wherein a light-shielding member is arranged between the second boundary region and the third boundary region, and no light-shielding member is arranged in the first boundary region.

14. A method of manufacturing a color filter array comprising a first color filter, a second color filter, and a third color filter that are arranged on a base member and respectively have different colors, the method comprising:
forming the first color filter;
forming the second color filter after the forming the first color filter; and
forming the third color filter before the forming the first color filter or between the forming the first color filter and the forming the second color filter,
wherein after the forming the first color filter and the forming the third color filter and before the forming the second color filter, the first color filter has an upper portion in contact with the third color filter and a lower portion that is arranged below the upper portion in a direction perpendicular to a surface of the base member, and is not in contact with the third color filter, and in the forming the second color filter, a concave portion formed between the lower portion and the third color filter is filled with part of the second color filter.

15. The method according to claim 14, wherein the first color filter is formed by using a negative photosensitive material, the forming the first color filter includes coating with the photosensitive material and exposing a region of the coated photosensitive material which forms the first color filter, and in the exposing, an amount of exposure light in a region serving as an outer edge portion of the first color filter is smaller than an amount of exposure light in a region serving as a central portion of the first color filter.

16. The method according to claim 14, wherein the first color filter is a color filter that transmits light in a blue band, the second color filter is a color filter that transmits light in a red band, and the third color filter is a color filter that transmits light in a green band.

17. The method according to claim 14, wherein the first color filter is a color filter that transmits light in a green band, the second color filter is a color filter that transmits light in a red band, and the third color filter is a color filter that transmits light in a blue band.
